(19) United States
(12) Patent Application Publication
(10) Pub. No.: US 2017/0274478 A1
(43) Pub. Date: Sep. 28, 2017

(54) SOLDER-COATED BALL AND METHOD FOR MANUFACTURING SAME

(71) Applicant: HITACHI METALS, LTD., Minato-ku, Tokyo (JP)

(72) Inventors: Tsutomu NOZAKA, Yasugi-shi, Shimane (JP); Hidehito MORI, Suita-shi, Osaka (JP)

(73) Assignee: Hitachi Metals, Ltd., Minato-ku, Tokyo (JP)

(21) Appl. No.: 15/503,939

(22) PCT Filed: Jul. 16, 2015
(86) PCT No.: PCT/JP2015/070383

§ 371 Date: Feb. 14, 2017

(30) Foreign Application Priority Data
Aug. 18, 2014 (JP) 2014-166137

(51) Int. Cl. B23K 35/02; B23K 35/26; B23K 1/00; B22F 9/24; H01L 23/00; B22F 1/02; C23C 18/16; C23C 18/38; C25D 3/60; C25D 5/40; B23K 35/30; B22F 1/00

(52) U.S. Cl. CPC B23K 35/0244; B23K 35/3033; B23K 35/302; B23K 35/262; B23K 1/0016; B22F 9/24; B22F 1/0003; B22F 1/025; C23C 18/1637; C23C 18/1653; C23C 18/38; C25D 3/60; C25D 5/40; H01L 24/13; H01L 24/11; B22F 2009/245; B22F 2301/15; B22F 2301/10; B22F 2301/30; B22F 2303/30; B22F 2998/10; H01L 2224/13014; H01L 2224/13083; H01L 2224/13101; H01L 2224/13147; H01L 2224/13111; H01L 2224/13155; H01L 2224/1357; H01L 2224/11464; H01L 2224/11462

(57) ABSTRACT

A solder-coated ball (10A) includes a spherical core containing Ni and P; and a solder layer (12) formed to coat the core (11). A solder-coated ball (10B) further includes a Cu plating layer (13) formed between the core (11) and the solder layer (12). A solder-coated ball (10C) further includes an Ni plating layer (14) formed between the Cu plating layer (13) and the solder layer (12).

### TECHNICAL FIELD

The present invention relates to a solder-coated ball preferably usable as, for example, an input/output terminal of a semiconductor package, and a method for manufacturing the same.

### BACKGROUND ART

A solder-coated ball is mainly used to connect parts of an electric or electronic device. Specifically, a solder-coated ball is used as, for example, an input/output terminal of a semiconductor package such as a QFP (Quard Flat Package) including lead terminals around a part, a BGA (Ball Grid Array), which is relatively compact and may possibly include a great number of pins, a CSP (Chip Size Package) or the like. Recently, a solder-coated ball having a particle diameter of 150 μm or less is desired in order to realize a semiconductor package having a smaller size and a higher density.

A conventionally used solder-coated ball uses Cu (copper) as a core (such a solder-coated ball may be referred to as a “Cu core solder-coated ball”) for the small variance thereof in the particle diameter and the sphericity. However, it is not easy to mass-produce a Cu core (may be referred to as a “Cu ball”) that has a particle diameter of 150 μm or less and has a shape close to a sphere. Various methods for manufacturing such a Cu core have been examined.

For example, Patent Document 1 describes as follows. A Cu thin cable having a diameter of 15 to 30 μm was press-cut to form a cylindrical chip, and the chip was formed into a sphere in a plasma atmosphere (referred to as a “plasma spheroidization process”); and as a result, a Cu ball having a particle diameter (precision, yield) of 40 μm (±5 μm; about 98%) was manufactured.

### CITATION LIST

### Patent Literature

Patent Document 1: Japanese Laid-Open Patent Publication No. 2005-036301

### SUMMARY OF INVENTION

### Technical Problem

Even the method for manufacturing the Cu ball described in Patent Document 1 is not considered to allow the Cu balls to be mass-produced sufficiently easily, and the manufacturing method is costly. With the manufacturing method of Patent Document 1, a press device for cutting the Cu thin cable with high precision to form a microscopic Cu chip and also a plasma spheroidization device need to be prepared, an oxide layer on a surface of the Cu chip needs to be removed or oxidation of the surface of the Cu chip needs to be suppressed, and these devices need to be stably driven. This is costly and time-consuming.

The present invention made to solve the above-described problems has an object of providing a microscopic solder-coated ball highly suitable for mass-production and a method for manufacturing the same.

### Solution to Problem

A solder-coated ball in an embodiment according to the present invention includes a spherical core containing Ni and P; and a solder layer formed to coat the core.

In an embodiment, the solder-coated ball further includes a Cu plating layer formed between the core and the solder layer.

In an embodiment, the solder-coated ball further includes an Ni plating layer formed between the Cu plating layer and the solder layer.

In an embodiment, the Cu plating layer has a thickness of 0.01 μm or greater and 50 μm or less.

In an embodiment, the solder-coated ball further includes an Ni plating layer formed between the core and the solder layer.

In an embodiment, the solder layer has a thickness of 0.01 μm or greater and 50 μm or less.

In an embodiment, the core has an average particle diameter of 150 μm or less and a sphericity of 0.98 or greater. The sphericity is preferably 0.99 or greater. The average particle diameter of the core is 1 μm or greater.

In an embodiment, the core contains P at 1% by mass or greater and 15% by mass or less, Cu optionally incorporated at 18% by mass at most and Sn optionally incorporated at 10% by mass at most, and the remaining part contains Ni and unavoidable impurities. Namely, it is preferable that the core is selected as necessary from a core containing Ni and P, a core containing Ni, P and Cu, and a core containing Ni, P, Cu and Sn.

A method for manufacturing a solder-coated ball in an embodiment according to the present invention is a method for producing the solder-coated ball described in any of the above. A step of preparing the core of the method includes a step of manufacturing, by an electroless reduction method, a powder of spherical particles containing Ni and P, the powder fulfilling [(d90−d10)/d50]≦0.8, where particles exhibiting 90% by volume, 10% by volume and 50% by volume in an accumulated volume distribution curve obtained by a laser diffraction/scattering method respectively have particle diameters of d90, d10 and d50. It is preferable that the powder of the spherical particles containing N and P fulfills [(d90−d10)/d50]<0.7.

In an embodiment, the method for manufacturing the solder-coated ball further includes a step of forming a solder layer by electrolytic plating, the solder layer coating the core.

### Advantageous Effects of Invention

An embodiment according to the present invention provides a solder-coated ball including a core having a surface entirely coated with a solder. The solder-coated ball has, for example, an average particle diameter of 150 pun or less and a sphericity of 0.98 or greater, and is highly suitable to mass-production. An embodiment according to the present invention provides a method for producing such a solder-coated ball at high mass-productivity.

### BRIEF DESCRIPTION OF DRAWINGS

FIG. 1(a), FIG. 1(b) and FIG. 1(c) are respectively schematic cross-sectional views of solder-coated balls 10A, 10B and 10C in an embodiment according to the present invention.

FIG. 2(a) is an SEM image of an NiP powder in experiment example 1, FIG. 2(b) is an SEM image of an NiP powder in experiment example 2, FIG. 2(c) is an SEM image of an NiP powder in experiment example 3, and FIG. 2(d) is an SEM image of an NiP powder in experiment example 4.

FIG. 3(a) shows an SEM image of a cross-section of a particle obtained after a Cu plating layer is formed on an NiP particle in experiment example 5 and before a solder layer is formed, and FIG. 3(b) shows an SEM image of a cross-section of a solder-plated NiP particle (solder-coated ball) in experiment example 6.

### DESCRIPTION OF EMBODIMENTS

Hereinafter, a solder-coated ball and a method for manufacturing the same in an embodiment according to the present invention will be described with reference to the drawings.

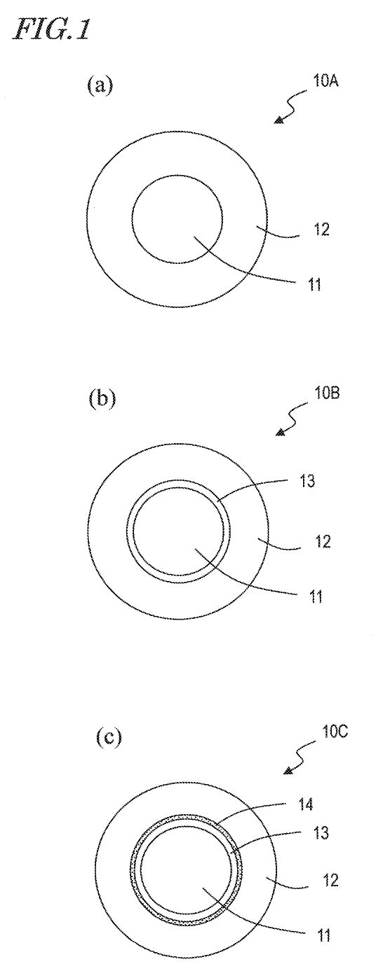

FIG. 1(a) FIG. 1(b) and FIG. 1(c) are respectively schematic cross-sectional views of solder-coated balls 10A, 10B and 10C in an embodiment according to the present invention.

The solder-coated ball 10A shown in FIG. 1(a) includes a spherical (ball-like) core 11 containing Ni (nickel) and P (phosphorus) and a solder layer 12 formed to coat the core 11. Unlike the solder-coated ball 10A, the solder-coated ball 10B shown in FIG. 1(b) further includes a Cu (copper) plating layer 13 formed between the core 11 and the solder layer 12. Unlike the solder-coated ball 10B, the solder-coated ball 10C shown in FIG. 1(c) further includes an Ni plating layer 14 formed between the Cu plating layer 13 and the solder layer 12. Regarding the solder-coated ball 10C shown in FIG. 1(c), the Cu plating layer 13 may be omitted so that the Ni plating layer 14 is directly formed on a surface of the core 11. Regarding the solder-coated ball 10C shown in FIG. 1(c), another Ni plating layer may be formed directly on the surface of the core 11 so that the Cu plating layer 13 and the Ni plating layer 14 are formed on the another Ni plating layer. In the case where the another Ni plating layer is provided, the Ni plating layer 14 may be omitted.

The core 11 included in each of the solder-coated balls 10A, 10B and 10C is a spherical (ball-like) core containing Ni and P. As the core 11, an NiP particle described in Japanese Laid-Open Patent Publication No. 2009-197317 (Japanese Patent No. 5327582) filed by the present applicant is preferably usable. Japanese Laid-Open Patent Publication No. 2009-197317 is incorporated herein in its entirety by reference. Hereinafter, the core 11 may be referred to as the “NiP core 11”.

The NiP core 11 contains Ni as a main component and may also contain Cu (copper) in addition to P (phosphorus). In the case of containing Cu, the NiP core 11 may further contain Sn (tin).

For example, the NiP core 11 contains P at 1% by mass or greater and 15% by mass or less, Cu optionally incorporated at 18% by mass at most, and Sn optionally incorporated at 5% by mass at most. The remaining part contains Ni and unavoidable impurities. The unavoidable impurities contained in the NiP core 11 are derived from a component of a solution used for manufacturing the NiP core 11, and are mainly C (carbon) and O (oxygen). Regarding the contents of C and O, it is preferable to suppress C at 0.1% by mass or less and to suppress O at 0.8% by mass or less. In this manner, the volume resistivity of the NiP core 11 is suppressed from increasing, and the adherence with the solder layer 12 or the Cu plating layer 13 formed on the surface of the NiP core 11 is suppressed from decreasing. Herein, “% by mass” of each of the elements refers to a content of the element with respect to the entirety of the NiP core 11.

The contents of P, Cu and Sn influence the hardness, the volume resistivity (conductivity), the particle diameter and the particle size distribution of the NiP particles. When the content of any of the elements increases, the volume resistivity increases. Therefore, the upper limit of the content of each element is determined mainly by the required volume resistivity. When the content of any of the elements is too high, it may be difficult to form the particle into a sphere having a sphericity of 0.98 or higher, or in some cases, the particle may not be formed into a sphere. The lower limit of the content of each element is determined by the amount required to obtain the intended particle size and/or particle size distribution.

This will be described in more detail. P (1% by mass or greater and 15% by mass or less) provides a hardness and a conductivity required as a conductive particle (core). Incorporation of P realizes an NiP particle having a structure that includes a crystalline substance in a central part and an amorphous intermetallic compound dispersed in a surface layer. Incorporation of Cu (0.01% by mass or greater and 18% by mass or less) provides an effect of improving the monodispersity. Incorporation of Sn (0.05% by mass or greater and 5% by mass or less) in addition to Cu provides an effect of further improving the monodispersity.

An NiP particle is manufactured as follows, for example. An aqueous solution of nickel salt and an aqueous solution of a P-containing reductant are mixed together to form a core of a microscopic particle, and then Ni and P are deposited from the core by electroless reduction. This manufacturing method (referred to as an “electroless reduction method”) allows NiP particles having a predetermined particle diameter to be mass-produced stably, efficiently and at low cost. For example, in the case where particles exhibiting 90% by volume, 10% by volume and 50% by volume in an accumulated volume distribution curve obtained by a laser diffraction/scattering method respectively have particle diameters of d90, d10 and d50, an NiP powder (aggregation of NiP particles) having a particle size distribution that fulfills [(d90−d10)/d50]≦0.8 is obtained. Regarding the above-described manufacturing method, in the step of mixing the aqueous solution of nickel salt and the aqueous solution of the P-containing reductant, Cu ion may be incorporated into the aqueous solution of nickel salt. In this case, an NiP particle having a composition of Ni—Cu—P is obtained. In the step of mixing the aqueous solution of nickel salt and the aqueous solution of the P-containing reductant, Cu ion and Sn ion may be incorporated into the aqueous solution of nickel salt. In this case, an NiP particle having a composition of Ni—Cu—Sn—P is obtained.

The above-described manufacturing method provides an NiP powder of NiP particles having an average particle diameter of 150 μm or less and a sphericity of 0.98 or greater. The lower limit of the average particle diameter of the NiP powder manufactured by the above-described manufacturing method is about 1 μm.

On the NiP powder described above, the solder layer 12 is formed by electrolytic plating. The solder layer 12 has a thickness of, for example, 0.01 μm or greater and 50 μm or less. Adjustment on the thickness of the solder layer 12 allows the diameter of the solder-coated ball 10A obtained as a final product to be controlled. The solder layer 12 may be formed of any of a wide range of known solder materials. For example, a lead-free solder material such as Sn-3Ag-0.5Cu or the like is preferably usable.

The Cu plating layer 13 and the Ni plating layer 14 are formed by electroless plating or electrolytic plating. The Cu plating layer 13 has a thickness of, for example, 0.01 μm or greater and 50 μm or less. The Ni plating layer 14 has a thickness of, for example, 0.01 μm or greater and 50 μm or less. The Ni plating layer 14 is expected to provide an effect of suppressing generation of a brittle intermetallic compound caused by Sn contained in the solder layer 12 and Cu contained in the Cu plating layer 13. The thickness of the Cu plating layer 13 and/or the thickness of the Ni plating layer 14 may be adjusted in order to control the diameter of the solder-coated ball 10B or 10C obtained as a final product, like the thickness of the solder layer 12.

The solder-coated balls 10B and 10C each include the Cu plating layer 13 formed to coat the NiP core 11. Before the solder layer 12 and the Ni plating layer 14 are formed, the assembly of the NiP core 11 and the Cu plating layer 13 appears the same as the Cu core, and the wettability of the assembly with the solder layer is the same as that of the Cu core. In the case where the thickness of the Cu plating layer 13 is made sufficiently large, the assembly may have a hardness equivalent to that of the Cu core. As is well known, the Ni plating layer 14 has an effect of improving the adherence of the assembly with the solder layer 12.

Hereinafter, experiment examples will be shown. In the following description, the “average particle diameter” refers to the diameter of the particles exhibiting 50% by mass in an accumulated volume distribution curve obtained by a laser diffraction/scattering method performed using, as a sample, an NiP powder of NiP particles, namely, refers to d50. The “sphericity” is a value obtained as follows. The maximum diameter of a projected image, and an equivalent circle diameter thereof, were measured by an image measurement system using collimated transmitted light, and the equivalent circle diameter was divided by the maximum diameter. The composition of the NiP particles was measured by use of an inductively coupled plasma (ICP) optical emission spectrometer (ICPE-9000 produced by Shimadzu Corporation).

### Experiment Example 1

Nickel sulfate hexahydrate, copper sulfate pentahydrate, and sodium stannate trihydrate were mixed such that the molar ratio of Ni and Cu would be Ni/Cu=29 and such that the molar ratio of Ni and Sn would be Ni/Sn=5.8. The resultant substance was dissolved in pure water to prepare 15 (dm³) of an aqueous solution of metal salt.

Next, sodium acetate was dissolved in pure water to obtain a concentration of 3.0 (kmnol/m³), and sodium hydroxide was incorporated thereto to prepare 15 (dm³) of a pH-adjusted aqueous solution.

The aqueous solution of metal salt and the pH-adjusted aqueous solution were stirred and mixed to obtain 30 (dm³) of a mixture aqueous solution. The mixture aqueous solution had a pH of 7.20.

The mixture aqueous solution was heated to, and kept at, 343 (K) by an external heater while being bubbled with N₂ gas, and was kept stirred.

Next, sodium phosphinate was dissolved in pore water at a concentration of 1.8 (kmol/m³) to prepare 15 (dm³) of an aqueous solution of reductant, and the aqueous solution of reductant was heated to 343 (K) also by an external heater.

In the state where 30 (dm³) of the mixture aqueous solution and 15 (dm³) of the aqueous solution of reductant had a temperature of 343±1 (K), these solutions were mixed, and an NiP powder was obtained by the electroless reduction method.

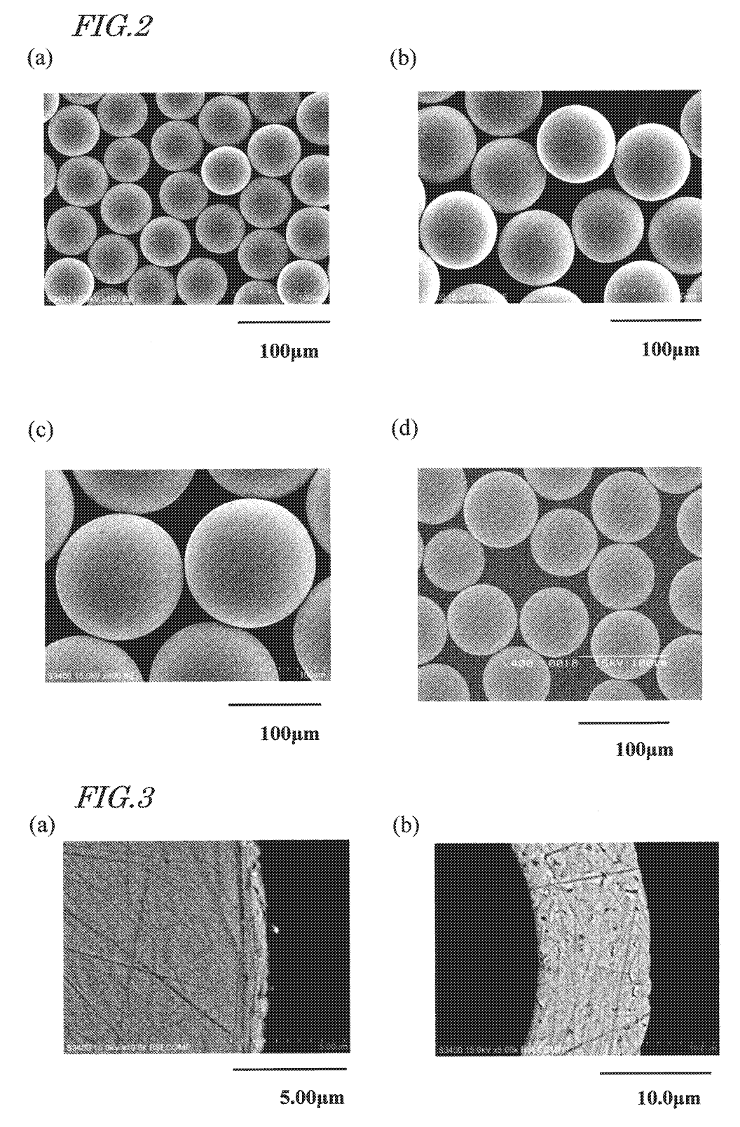

The average particle diameter d50 of the obtained NiP powder was 56.1 m, and the value of [(d90−d10)/d50] thereof was 0.55. The sphericity of the obtained NiP powder was 0.995. FIG. 2(a) shows an SEM image of the NiP powder. As can be seen from FIG. 2(a), individual NiP particles had a shape close to a sphere, and the obtained NiP powder had a high level of monodispersity.

The composition of the NiP particles was as follows. The content of P was 5.3% by mass, the content of Cu was 4.310% by mass, the content of Sn was 0.159% by mass, and the remaining part contained Ni and unavoidable impurities.

The results are shown in Table 1. Table 1 also shows the results of experiment examples 2 through 6.

### Experiment Example 2

NiP particles were manufactured by the electroless reduction method under the same conditions as those of experiment example 1 except that the amount of sodium hydroxide was adjusted such that the mixture aqueous solution had a pH of 7.16. FIG. 2(b) shows an SEM image of the obtained NiP powder. As can be seen from FIG. 2(b), individual NiP particles had a shape close to a sphere, and the obtained NiP powder had a high level of monodispersity. The average particle diameter d50 was 90.2 μm, and the value of [(d90−d10)/d50] was 0.66.

### Experiment Example 3

Microscopic particles were manufactured by the electroless reduction method in substantially the same manner as that of experiment example 1 except that nickel sulfate hexahydrate, copper sulfate pentahydrate, and sodium stannate trihydrate were mixed such that the molar ratio of Ni and Cu would be Ni/Cu=21.75 and such that the molar ratio of Ni and Sn would be Ni/Sn=5.8. The mixture aqueous solution had a pH of 7.12.

FIG. 2(c) shows an SEM image of the obtained NiP powder. As can be seen from FIG. 2(c), individual NiP particles had a shape close to a sphere, and the obtained NiP powder had a high level of monodispersity. The average particle diameter d50 was 149.1 μm, and the value of [(d90−d10)/d50] was 0.46.

### Experiment Example 4

Nickel sulfate hexahydrate and copper sulfate pentahydrate were mixed such that the molar ratio of Ni and Cu would be Ni/Cu=39. The resultant substance was dissolved in pure water to prepare 15 (dm³) of an aqueous solution of metal salt.

Fifteen (dm³) of a pH-adjusted aqueous solution containing 0.65 (kmol/m³) of sodium acetate and 0.175 (kmol/m³) of disodiummaleate was prepared.

The aqueous solution of metal salt and the pH-adjusted aqueous solution were stirred and mixed to obtain 30 (dm³) of a mixture aqueous solution. The mixture aqueous solution had a pH of 8.2.

The mixture aqueous solution was heated to, and kept at, 343 (K) by an external heater while being bubbled with N₂ gas, and was kept stirred.

After this, substantially the same process as that of experiment example 1 was performed to manufacture an NiP powder by the electroless reduction method.

FIG. 2(d) shows an SEM image of the obtained NiP powder. As can be seen from FIG. 2(d), individual NiP particles had a shape close to a sphere, and the obtained NiP powder had a high level of monodispersity. The average particle diameter d50 was 67.1 μm, and the value of [(d90−d10)/d50] was 0.51. The NiP powder did not contain Sn, and the result of the composition analysis showed that the content of Sn was less than the detection limit.

### Experiment Example 5

A Cu plating layer was formed on a surface of each of the Ni—P particles obtained in experiment example 1 by an electroless Cu plating method described below, with a target thickness of the Cu plating layer being about 0.5 μm.

The NiP powder was immersed in an oxide film removal solution (Top UBP Enuakuchi produced by Okuno Chemical Industries Co., Ltd.) of 70° C. for 3 minutes while the container was vibrated by hand. A naturally generated oxide film on the surface of each of the NiP particles was removed by this activation process. Then, the NiP powder extracted by absorption and infiltration was immersed in pure water and subjected to ultrasonic washing for 3 minutes.

Next, the NiP powder was immersed in a catalyst solution (ICP Akusera KCR produced by Okuno Chemical Industries Co., Ltd.) of 30° C. for 3 minutes to generate a Pd core on the surface of each of the NiP particles). The Pd core is a start point of deposition of the electroless Cu plating layer.

The obtained NiP powder was subjected to ultrasonic washing as described above and then was put into an electroless plating solution (OPC Copper AF produced by Okuno Chemical Industries Co., Ltd.). While the electroless Cu plating solution of 60° C. was air-bubbled, and at the same time, was stirred at a rate of 200 times/min. by use of a stirrer, the NiP powder was put into the solution. In this state, electroless Cu plating was performed for 4 hours. The NiP powder having a Cu plating layer formed thereon was extracted, subjected to ultrasonic washing, and then dried at 60° C.

FIG. 3(a) shows an SEM image of a cross-section of the obtained Cu-plated NiP particle. The average particle diameter d50 of the Cu-plated NiP powder was 57.5 μm, and the value of [(d90−d10)/d50] thereof was 0.56. The sphericity of the Cu-plated NiP particles was 0.995, which was not changed from the sphericity of the NiP particles in experiment example 1. It was confirmed that the sphericity was not decreased by Cu plating, namely, that the Cu plating layer was formed to have a uniform thickness (0.7 μm). It is seen from the SEM image of FIG. 3(a) that the Cu plating layer was formed with a uniform thickness.

Then, a solder layer was formed to coat the Cu plating layer to obtain solder-coated balls each including the Cu plating layer between the NiP core and the solder layer. The solder layer was formed by an electrolytic solder plating method described in experiment example 6.

### Experiment Example 6

A solder layer having a composition of Sn-3.0Ag-0.5Cu was formed on a surface of each of the Ni—P particles obtained in experiment example 1 by an electrolytic solder plating method described below, with a target thickness of the solder plating layer being about 10 μm.

The NiP powder was immersed in a 10% aqueous solution of hydrochloric acid for 3 minutes while the container was vibrated by hand. A naturally generated oxide film on the surface of each of the NiP particles was removed by this activation process. Then, the NiP powder extracted by absorption and infiltration was immersed in pure water and subjected to ultrasonic washing for 3 minutes.

Next, ammonia was incorporated into a solution containing tin methanesulfonate (containing 18 g/L of Sn), silver methanesulfonate (containing 1.0 g/L of Ag) and copper methanesulfonate (containing 2.2 g/L of Cu), and the resultant solution was adjusted to have a pH of 4.0. Thus, a solder plating solution was prepared.

The solder plating solution was used to perform electrolytic plating using Sn as an anode electrode at a current density of 0.4 A/dm² and room temperature (25° C.) by use of a high-speed rotation plating device (see, for example, WO2013/141166) to form a solder layer having a composition of Sn-3.0Ag-0.5Cu (the numerical values correspond to % by mass) to a thickness of about 10 μm on the surface of each of the NiP particles. The NiP powder having the solder layer formed thereon was extracted, subjected to ultrasonic washing, and then dried at 50° C.

FIG. 3(b) shows an SEM image of a cross-section of the obtained solder-plated NiP particle (solder-coated ball). The average particle diameter d50 of the solder-plated NiP powder was 76.6 μm, and the value of [(d90−d10)/d50] thereof was 0.56. The sphericity of the solder-plated NiP particles was 0.994, which was not changed almost at all from the sphericity of the NiP particles in experiment example 1. It was confirmed that the sphericity was not decreased even when a relatively thick solder layer was formed, namely, that the solder plating layer was formed to have a substantially uniform thickness (10.25 μm). It is seen from the SEM image of FIG. 3(b) that the solder plating layer was formed with a uniform thickness.

TABLE 1

| | AVERAGE | | | | | | |
|---|---|---|---|---|---|---|---|
| | PARTICLE | | COMPOSITION OF NiP | | | | |
| | DIAMETER | | PARTICLE (% BY MASS) | | | | |
| | (μm) | SPHERICITY | P | Cu | Sn | Ni* | REMARKS |
| EXPERIMENT | 56.1 | 0.995 | 5.3 | 4.31 | 0.16 | REMAIN- | |
| EXAMPLE 1 | | | | | | ING PART | |
| EXPERIMENT | 90.2 | 0.996 | 5.7 | 4.12 | 0.24 | REMAIN- | |
| EXAMPLE 2 | | | | | | ING PART | |
| EXPERIMENT | 149.1 | 0.995 | 5.8 | 4.90 | 0.26 | REMAIN- | |
| EXAMPLE 3 | | | | | | ING PART | |
| EXPERIMENT | 67.1 | 0.994 | 6.0 | 2.75 | <0.01 | REMAIN- | |
| EXAMPLE 4 | | | | | | ING PART | |
| EXPERIMENT | 57.5 | 0.995 | SAME AS EXPERIMENT | | | | EXPERIMENT |
| EXAMPLE 5 | | | EXAMPLE 1 | | | | EXAMPLE 1 + |
| | | | | | | | Cu PLATING |
| EXPERIMENT | 76.6 | 0.994 | | | | | EXPERIMENT |
| EXAMPLE 6 | | | | | | | EXAMPLE 1 + |
| | | | | | | | SOLDER |
| | | | | | | | PLATING |

*Contains unavoidable impurities

### INDUSTRIAL APPLICABILITY

A solder-coated ball according to the present invention is usable for, for example, electric connection for a compact and highly dense semiconductor package.

### REFERENCE SIGNS LIST

10A, 10B, 10C Solder-coated ball
11 Core (NiP core)
12 Solder layer (solder plating layer)
13 Cu plating layer
14 Ni plating layer

1. A solder-coated ball, comprising:
a spherical core containing Ni and P; and
a solder layer formed to coat the core.

2. The solder-coated ball according to claim 1, further comprising a Cu plating layer formed between the core and the solder layer.

3. The solder-coated ball according to claim 2, further comprising an Ni plating layer formed between the Cu plating layer and the solder layer.

4. The solder-coated ball according to claim 2, wherein the Cu plating layer has a thickness of 0.01 μm or greater and 50 μm or less.

5. The solder-coated ball according to claim 1, wherein the solder layer has a thickness of 0.01 μm or greater and 50 μm or less.

6. The solder-coated ball according to claim 1, wherein the core has an average particle diameter of 150 μm or less and a sphericity of 0.98 or greater.

7. The solder-coated ball according to claim 1, wherein the core contains P at 1% by mass or greater and 15% by mass or less, Cu optionally incorporated at 18% by mass at most and Sn optionally incorporated at 5% by mass at most, and the remaining part contains Ni and unavoidable impurities.

8. A method for manufacturing solder-coated ball comprising a spherical core containing Ni and P, and a solder layer formed to coat the core, the method comprising a step of preparing the core,
wherein the step includes a step of manufacturing, by an electroless reduction method, a powder of spherical particles containing Ni and P, the powder fulfilling [(d90−d10)/d50]≦0.8, where particles exhibiting 90% by volume, 10% by volume and 50% by volume in an accumulated volume distribution curve obtained by a laser diffraction/scattering method respectively have particle diameters of d90, d10 and d50.

9. The method for manufacturing the solder-coated ball according to claim 8, further comprising a step of forming a solder layer by electrolytic plating, the solder layer coating the core.
